(19) United States
(12) Patent Application Publication
(10) Pub. No.: US 2023/0361064 A1
(43) Pub. Date: Nov. 9, 2023

(54) METHOD OF MANUFACTURING AN INTERCONNECTION STRUCTURE OF AN INTEGRATED CIRCUIT

(71) Applicant: STMicroelectronics (Crolles 2) SAS, Crolles (FR)

(72) Inventors: Marion CROISY, Froges (FR); Sylvie DEL MEDICO, CROLLES (FR)

(73) Assignee: STMicroelectronics (Crolles 2) SAS, Crolles (FR)

(21) Appl. No.: 18/311,779

(22) Filed: May 3, 2023

(30) Foreign Application Priority Data
May 9, 2022 (FR) 2204351

(51) Int. Cl. H01L 23/00; H01L 23/31; H01L 21/56

(52) U.S. Cl. CPC H01L 24/05; H01L 23/3192; H01L 21/56; H01L 24/13; H01L 24/45; H01L 2224/05647; H01L 2224/04042; H01L 2224/0401; H01L 2224/13147; H01L 2224/45147

(57) ABSTRACT

The present description relates to a method of manufacturing an end of an interconnection structure of an integrated circuit, the method including: providing an integrated circuit including an interconnection structure including copper interconnection elements at least partly extending through an insulating layer and flush with a first surface of said interconnection structure; forming a protection layer on the first surface of the interconnection structure, said protection layer including a material adapted to protecting the copper of the interconnection elements; forming a passivation layer on the protection layer, the passivation layer having a first thickness; and forming a first opening in the passivation layer across a second thickness smaller than the first thickness, to keep a residual passivation layer at the bottom of the first opening.

### CROSS-REFERENCE TO RELATED APPLICATION(S)

This application claims the priority benefit of French patent application number FR2204351, filed on May 9, 2022, entitled “Procédé de fabrication d'une structure d'interconnexion de circuit intégré,” which is hereby incorporated by reference to the maximum extent allowable by law.

### TECHNICAL FIELD

The present disclosure generally relates to electronic circuits such as integrated circuits, and more particularly, to ends of interconnection structures of integrated circuits (FBEOL, Far Back End Of Line) including copper metallizations, and methods of manufacturing these structures.

### Description of the Related Art

Integrated circuits (IC) are generally formed of a plurality of stacked layers made of semiconductor, insulating, and conductive materials.

In a first phase (front end of line, FEOL) of an integrated circuit manufacturing process, components such as, among others, transistors, diodes, resistors, and/or capacitors, are formed inside and/or on top of a substrate, which may include a semiconductor layer.

In a second phase (back end of line, BEOL) of the process, the components are interconnected by an electric interconnection structure. An interconnection structure typically includes metal conductive tracks (or lines), generally a plurality of metal tracks stacked in a plurality of levels and electrically insulated from one another by insulating layers. Vias cross one or a plurality of insulating layers of the interconnection structure to electrically couple together the metal tracks.

In a third phase of the process called FBEOL (far back end of line), which may be included in the BEOL phase, an end of the interconnection structure may be formed above the, or at the, last level of the interconnection structure. By end of interconnection structure, there is meant the level most distant from the substrate. This end of the structure may include at least one additional metal track and/or at least one metal pad to couple components of the integrated circuit to other locations of said integrated circuit or to couple the integrated circuit to another electronic circuit, for example, a printed circuit. The end of the interconnection structure may be adapted to easing the encapsulation of the integrated circuit in a resin to integrate said integrated circuit in an electronic package.

The vias, the metal tracks, as well as the additional metal track and/or the metal pad (more widely the interconnection elements) may be made of copper, which more and more replaces aluminum in electronic circuits. Indeed, copper being a better conductor than aluminum, copper interconnection elements may have smaller dimensions than those made of aluminum, and use less energy to conduct electricity therethrough.

An end of an interconnection structure including copper interconnection elements may enable to form a copper-to-copper contact, for example, by wire bonding, on the metal pad, for example, before encapsulation in a package, or through a metal pillar and/or a metal ball.

It is however preferable for the copper to be protected from air, or from any oxidizing and/or corrosive atmosphere, at least until the placing into contact and the encapsulation.

### BRIEF SUMMARY

There is a need for an interconnection structure for an integrated circuit which includes, at its end most distant from the substrate, a copper metallization which enables to protect the copper. As a shortcut, there is designated by “end” of the interconnection structure its end most distant from the substrate, and which is adapted to coupling components of the integrated circuit to other locations of said integrated circuit or to coupling the integrated circuit to another electronic circuit, for example, a printed circuit.

An embodiment overcomes all or part of the disadvantages of known interconnection structures.

An embodiment provides a method of manufacturing an end of an interconnection structure of an integrated circuit. The method includes providing an integrated circuit including an interconnection structure including copper interconnection elements at least partly extending through an insulating layer and flush with a first surface of said interconnection structure. The method includes forming a protection layer on the first surface of the interconnection structure, said protection layer including a material adapted to protecting the copper of the interconnection elements, for example from oxidation and/or from corrosion. The method includes forming a passivation layer on the protection layer, the passivation layer having a first thickness and forming a first opening in the passivation layer across a second thickness smaller than the first thickness, to keep a residual passivation layer at the bottom of the first opening.

According to an embodiment, the method further includes forming an additional insulating layer in the first opening and on the passivation layer, forming a second opening in the additional insulating layer, vertically in line with the first opening, from a first surface of said additional insulating layer to the residual passivation layer, and removing the residual passivation layer from the bottom of the first opening.

According to an embodiment, the second opening has greater lateral dimensions than the first opening.

According to an embodiment, the passivation layer is a multilayer structure including at least a first passivation layer, for example, made of silicon nitride, on the protection layer, and at least another layer on the first passivation layer, the first passivation layer forming the residual passivation layer.

According to an embodiment, the at least another layer includes a dielectric layer, for example made of silicon dioxide, on the first passivation layer and a second passivation layer, for example made of silicon nitride, on the dielectric layer.

According to an embodiment, the first thickness of the passivation layer is in the range from 710 to 1,340 nm and the thickness of the residual passivation layer is in the range from 10 to 40 nm.

According to an embodiment, the step of forming of the first opening and/or the step of forming of the second opening and/or the step of removal of the residual passivation layer includes a dry etching step.

According to an embodiment the protection layer is formed by an atomic layer deposition technique and/or the passivation is formed by a chemical vapor deposition technique, for example a plasma-enhanced chemical vapor deposition technique.

An embodiment provides an integrated circuit including an interconnection structure including copper interconnection elements at least partly extending through an insulating layer and flush with a first surface of said interconnection structure. One end of the interconnection structure includes a protection layer on the first surface of the interconnection structure. The protection layer includes a material adapted to protecting the copper of the interconnection elements, for example, from oxidation and/or from corrosion. The end of the interconnection structure includes a passivation layer on the protection layer and a first opening in the passivation layer extending all the way to the protection layer.

According to an embodiment, the end of the interconnection structure further includes an additional insulating layer in the first opening and on the passivation layer and a second opening in the additional insulating layer, vertically in line with the first opening, at least a portion of said second opening extending all the way to the protection layer.

According to an embodiment, the second opening has greater lateral dimensions than the first opening.

According to an embodiment, the passivation layer is a multilayer structure including a first passivation layer, for example, made of silicon nitride, on the protection layer, a dielectric layer, for example, made of silicon dioxide, on the first passivation layer, and a second passivation layer, for example, made of silicon nitride, on the dielectric layer.

According to an embodiment, the end of the interconnection structure is obtained by implementing the method according to an embodiment.

According to an embodiment, the integrated circuit further includes an electric contact element having a first end coupled to at least one of the interconnection elements, the electric contact element being for example a wire, a pillar, and/or a ball.

According to an embodiment, the protection layer is an insulating or dielectric material, in particular including aluminum and/or hafnium, and/or has a thickness in the range from 1 nm to 100 nm, for example, from 5 nm to 50 nm.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A, FIG. 1B, FIG. 1C, FIG. 1D, and FIG. 1E are cross-section views illustrating an interconnection structure at the end of the successive steps of an example of a manufacturing method, according to an embodiment;

FIG. 2A, FIG. 2B, FIG. 2C, FIG. 2D, FIG. 2E, and FIG. 2F are cross-section views illustrating an interconnection structure at the end of the successive steps of an example of a manufacturing method, according to an embodiment;

FIG. 3 is a cross-section view partially showing an example of an integrated circuit after encapsulation, where an interconnection pad of the interconnection structure is placed in contact with a copper wire, according to an embodiment; and

FIG. 4 is a cross-section view partially showing another example of an integrated circuit where an interconnection pad of the interconnection structure is placed in contact with a copper pillar, according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the lower layers of the interconnection structure and, more generally, the lower layers of the integrated circuit, are not shown.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

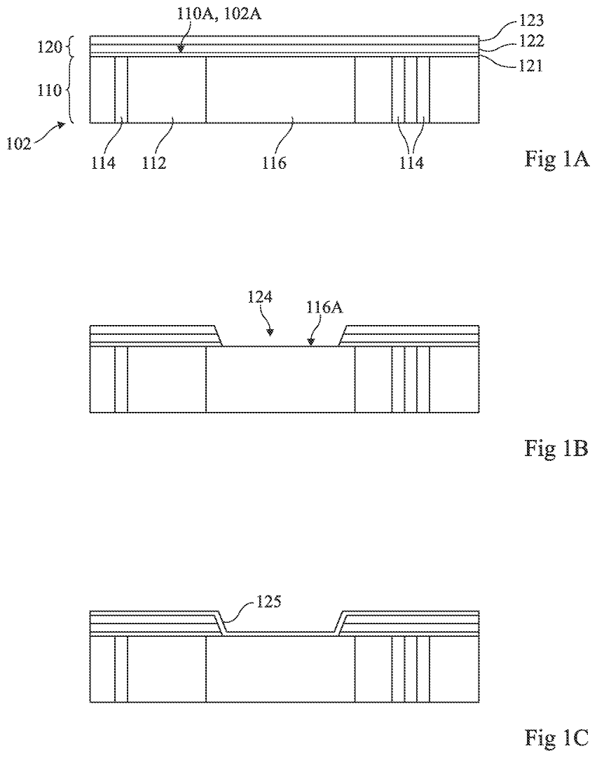

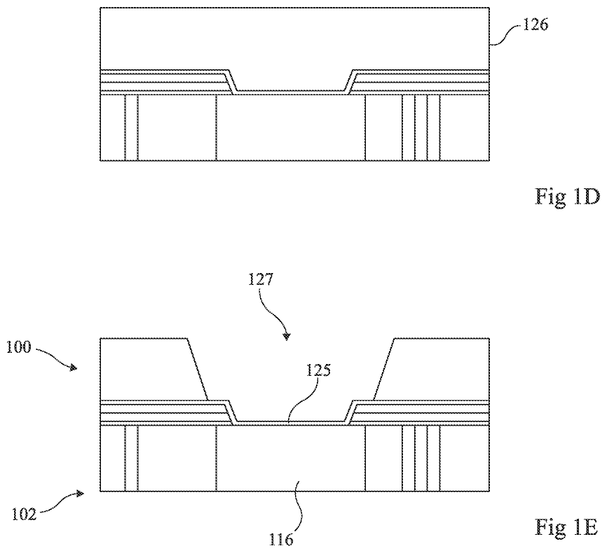

FIG. 1A shows an initial integrated circuit structure (a portion of which only is shown in FIGS. 1A, 1B, 1C, 1D, 1E) including an interconnection structure 102, an upper interconnection layer 110 of which has been shown. The lower layers of the interconnection structure, and more generally the lower layers of the integrated circuit, are not shown in FIGS. 1A-1E.

The upper interconnection layer 110 includes an insulating layer 112 crossed by lines 114 and a metal pad 116. Lines 114 and pad 116 are made of copper (Cu). Insulating layer 112 is for example made of silicon dioxide (SiO2). The copper interconnection elements, here the lines or the pad, are generally formed by a method called “Damascene” known by those skilled in the art. Lines 114 and pad 116 extend depthwise in insulating layer 112, and are flush with the upper surface 110A of upper interconnection layer 110 (which corresponds to the upper surface 102A of interconnection structure 102).

A passivation layer 120 is formed on upper interconnection layer 110. Passivation layer 120 is adapted to protecting the integrated circuit, and in particular the interconnection structure.

The passivation layer 120 is shown as a multilayer structure including:
a first passivation layer 121 on upper interconnection layer 110;
a dielectric layer 122 on first passivation layer 121; and
a second passivation layer 123 on dielectric layer 122.

The dielectric layer 122 may for example form a layer called “getter” intended to trap alkaline ions. First and second passivation layers 121, 123 may for example enable to form a physical barrier to the diffusion of alkaline ions.

The second passivation layer 123 is preferably thicker than first passivation layer 121.

The different layers of the multilayer passivation structure may be formed by a chemical vapor deposition technique (CVD).

First passivation layer 121 and second passivation layer 123 are formed of an insulating material, such as silicon nitride (SiN). Dielectric layer 122 is made of an insulating material, such as silicon dioxide (SiO2) or a multistack dielectric made of SiN and SiO2.

Then, as shown in FIG. 1B, a first opening (or trench) 124 is formed through passivation layers 121, 123 and dielectric layer 122, to expose a portion of the upper surface 110A of interconnection layer 110, and in particular at least a portion of the upper surface 116A of copper metal pad 116. For example, first opening 124 is formed by photolithography and etching steps, from the upper surface of second passivation layer 123.

Then, as shown in FIG. 1C, a protection layer 125 is formed, in the form of a coating, on the exposed surface of metal pad 116 and on lateral portions of first opening 124, that is, on etched portions of passivation layers 121, 123 and of dielectric layer 122.

The protection layer 125 may be formed by atomic layer deposition (ALD).

The protection layer 125 thus totally covers, preferably uniformly, the exposed surface of metal pad 116. Protection layer 125 is preferably made of an insulating or dielectric material, ensuring a protection of the copper against oxidation and/or corrosion phenomena, for example, made of an alloy or a compound including aluminum or hafnium.

Then, as shown in FIG. 1D, a step of forming of an additional insulating layer 126 is executed. For example, this insulating layer 126 is formed by passivation with a photosensitive organic material, for example, deposited by spin coating or by lamination, followed by a photolithographic process. Additional insulating layer 126 may comprise, for example, be, a polyimide, a polybenzoazole (PBO), an epoxy, a photosensitive organic material . . .

Then, as shown in FIG. 1E, a second opening (or trench) 127 is formed through insulating layer 126, vertically in line with first opening 124. This second opening is formed by structuring insulating layer 126, for example, by a photolithography and etching technique, to form an access to protection layer 125. The etching of insulating layer 126 stops at the interface with protection layer 125.

The second opening 127 is wider than the first opening 124, so that the surface of metal pad 116 is exposed through the two openings 124, 127, for example for subsequent steps of placing into contact of the metal pad and/or of encapsulation (molding) of the integrated circuit (steps not shown, known by those skilled in the art).

A disadvantage of this method is that, when insulating layer 126 is etched, at least a portion of protection layer 125, or even the entire portion of the protection layer covering the copper, is removed, with the risk for copper to be exposed to air.

The inventors provide an interconnection structure manufacturing method, as well as an interconnection structure enabling to answer the previously-described improvement needs, and to overcome all or part of the disadvantages of the previously-described interconnection structures. In particular, the inventors provide an interconnection structure manufacturing method, as well as an interconnection structure, enabling to maintain a protection of copper interconnection elements.

Embodiments of an interconnection structure manufacturing method, as well as an interconnection structure obtained by this method, will be described hereafter. The described embodiments are non-limiting and various variants will occur to those skilled in the art based on the indications of the present disclosure.

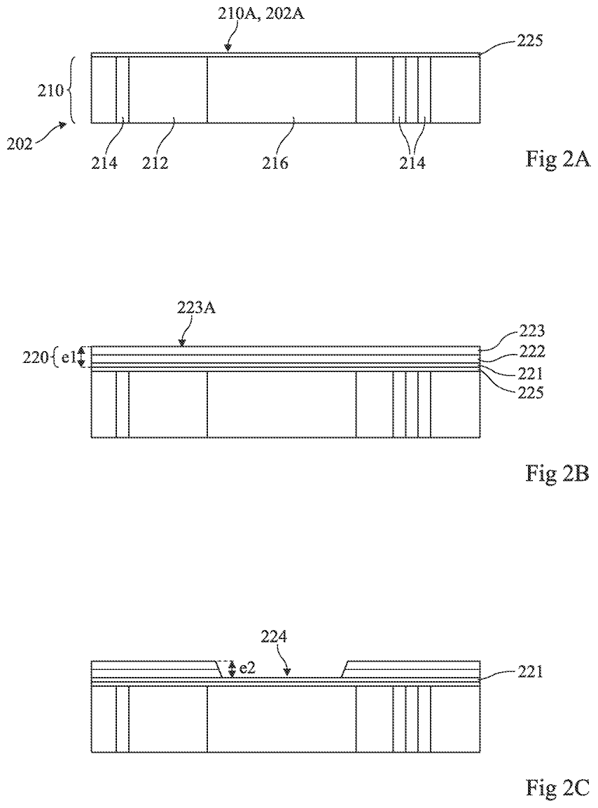

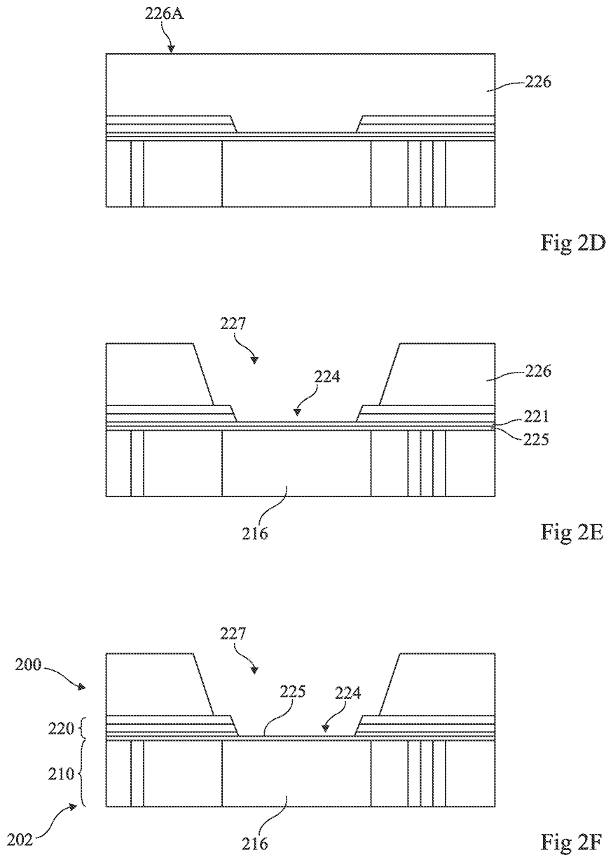

FIG. 2A shows an integrated circuit (a portion only thereof being shown in FIGS. 2A, 2B, 2C, 2D, 2E, 2F) including an interconnection structure 202, the upper interconnection layer 210 of which has been shown. The lower layers of the interconnection structure, and more generally, the lower layers of the integrated circuit, are not shown in FIGS. 2A-2F.

The upper interconnection layer 210 includes an insulating layer 212 crossed by lines 214 and a metal pad 216. Lines 214 and pad 216 are made of copper (Cu). Insulating layer 212 is for example made of silicon dioxide (SiO₂). The copper interconnection elements, here the lines and the pad, are generally formed by a method called “Damascene” known by those skilled in the art. Lines 214 and pad 216 extend depthwise in insulating layer 212 and are flush with the upper surface 210A of upper interconnection layer 210, which corresponds to the upper surface 202A of interconnection structure 202.

As shown in FIG. 2A, a protection layer 225 is formed on the upper surface 210A of upper interconnection layer 210.

The protection layer 225 may be formed in the form of a coating, preferably, by an atomic layer deposition technique (ALD), for example, a plasma-enhanced ALD or a thermal ALD. As a variant, the protection layer may be formed by a plasma-enhanced chemical vapor deposition technique (PECVD) or by any other adapted technique.

The protection layer 225 may have a thickness in the order of one nanometer or of some ten nanometers (that is, smaller than 100 nm). For example, the thickness of protection layer 225 is uniform and is in the range from 1 nm to 25 nm, more particularly from 5 nm to 15 nm.

The protection layer 225 is preferably made of an insulating or dielectric material, ensuring a protection of the copper against oxidation and/or corrosion phenomena, for example, made of an alloy or a compound including aluminum or hafnium. Examples of materials are: Al₂O₃, HfO₂, HfᵢAlⱼOₖ, AlN, AlᵢNⱼOₖ, HfNᵢ (where i, j, and k can be freely selected by those skilled in the art). Protection layer 225 may also be a stack formed of a plurality of layers including aluminum and/or hafnium and/or their alloys or composites, such as a stack including two or more from among HfO₂/Al₂O₃/AIN/HfNᵢ. Other materials or alloys are possible, provided that they can fulfill a function of protection against copper corrosion or degradation or oxidation phenomena, and, for example, that they can be deposited with a thickness within the above-identified range.

Then, as shown in FIG. 2B, a passivation layer 220, having a thickness e1, is formed on protection layer 225. Passivation layer 220 is adapted to protecting the integrated circuit, and in particular the interconnection structure.

The passivation layer 220 is shown as a multilayer structure including a first passivation layer 221 on protection layer 225, a dielectric layer 222 on first passivation layer 221, and a second passivation layer 223 on dielectric layer 222.

Dielectric layer 222 may for example form a layer called “getter” intended to trap alkaline ions. The first and second passivation layers 221, 223 may for example enable to form a physical barrier to the diffusion of alkaline ions.

The second passivation layer 223 is preferably thicker than first passivation layer 221. For example, the thickness of first passivation layer 221 may be in the range from approximately 10 to 40 nm, for example, equal to approximately 20 nm. The thickness of second passivation layer 223 may be in the range from approximately 300 to 700 nm, or even from 500 to 650 nm, for example, equal to approximately 600 nm.

The thickness of dielectric layer 222 may be in the range from approximately 400 to 600 nm, and is for example equal to approximately 500 nm.

The different layers of the multilayer passivation structure may be formed by a chemical vapor deposition (CVD) technique, particularly by a plasma-enhanced chemical vapor deposition (PECVD) technique.

The first passivation layer 221 and second passivation layer 223 are made of an insulating material, such as, preferably, silicon nitride (SiN), or silicon carbonitride (SiCN).

The dielectric layer 222 is made of an insulating material, such as silicon dioxide (SiO2) or a multistack dielectric made of SiN and SiO2.

Then, as shown in FIG. 2C, a first opening (or trench) 224 is formed through second passivation layer 223 and dielectric layer 222 vertically in line with copper metal pad 216, but keeping first passivation layer 221, or at least a thickness of first passivation layer 221, at the bottom of said first opening. For example, first opening 224 is formed by photolithography and dry etching steps, from the upper surface 223A of second passivation layer 223. The etching is for example a plasma etching where the plasma includes a mixture of octafluorocyclobutane and oxygen (C4F8/O2), or a mixture of hexafluorobutadiene and oxygen (C4F6/O2).

Then, as shown in FIG. 2D, a step of forming of an additional insulating layer 226 is executed. For example, this insulating layer 226 is formed by passivation with a photosensitive organic material, for example, deposited by spin coating or by lamination, followed by a photolithographic process. Additional insulating layer 226 may comprise, for example, be, a polyimide, a polybenzoazole (PBO), an epoxy, a photosensitive inorganic material . . .

Then, as shown in FIG. 2E, a second opening (or trench) 227 is formed through insulating layer 226 vertically in line with first opening 224. This second opening is formed by structuring insulating layer 226, from its upper surface 226A, for example, by a photolithography technique, to form an access to first passivation layer 221.

Thus, the maintaining of first passivation layer 221 enables to avoid for the exposed portion of protection layer 225, which covers the copper of metal pad 216, to be removed during the etching of insulating layer 226. The exposed copper interconnection elements, here metal pad 216, can thus remain protected.

Then, as shown in FIG. 2F, the exposed portion of first passivation layer 221 is removed, through openings 224 and 227, for example by dry etching. Insulating layer 226 with its opening 227 may be used as an etching mask for first passivation layer 221.

The integrated circuit 200 visible in FIG. 2F thus includes an interconnection structure 202 having its upper interconnection layer 210 including an insulating layer 212 crossed by lines 214 and a copper metal pad 216, lines 214 and pad 216 extending depthwise in insulating layer 212, and being flush with the upper surface 210A of upper interconnection layer 210, that is, with the upper surface 202A of interconnection structure 202. A protection layer 225, a passivation layer 220, and an insulating layer 226 are positioned in this order on upper interconnection layer 210. In other words, protection layer 225 is positioned between upper interconnection layer 210 and passivation layer 220. A first opening 224 in passivation layer 220 and a second opening 227 in insulator layer 226 vertically in line with the first opening are provided to access copper metal pad 216, which is protected by a protection layer 225.

The second opening 227 has lateral dimensions greater than or equal to those of the first opening 224, so that the surface of metal pad 216, protected by protection layer 225, is accessible through the two openings 224, 227, for example, for subsequent steps of placing into contact of the metal and/or encapsulation (molding) pad of the integrated circuit (steps not shown, known by those skilled in the art).

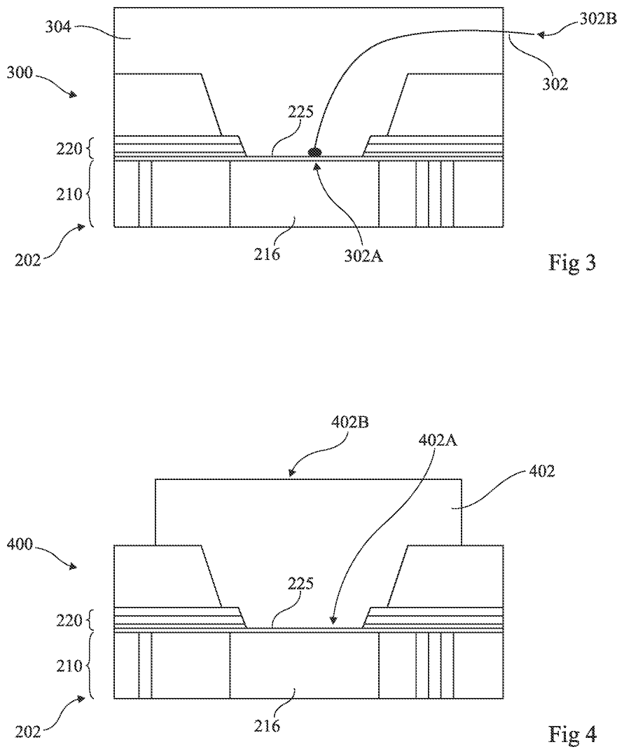

FIG. 3 shows an example of integrated circuit 300 where the copper pad 216 at the end of interconnection structure 202, and covered with protection layer 225, is coupled to a first end 302A of a copper wire 302, and then encapsulated in a resin 304 so that the second end 302B of the copper wire is accessible outside of resin 304. This for example enables to form a wire bonding type link to couple components of the integrated circuit to other locations of said integrated circuit or to another electronic circuit, for example, a printed circuit.

FIG. 4 shows another example of an integrated circuit 400 where the copper pad 216 at the end of interconnection structure 202, and covered with protection layer 225, is coupled to a first end 402A of a copper pillar 402. The copper pillar for example enables to couple components of the integrated circuit to other locations of said integrated circuit or to another electronic circuit, for example, a printed circuit.

According to a variant, the copper pillar may be topped with an end portion (not shown) made of a more flexible material substantially in the form of a ball or of a crushed ball, for example, a tin alloy, intended to form a contact of ball grid array (BGA) type.

According to another variant, the copper pillar is replaced with a more flexible material substantially in the form of a ball or of a crushed ball intended to form a contact of ball grid array (BGA) type.

Various embodiments and variants have been described. Those skilled in the art will understand that certain features of these various embodiments and variants may be combined, and other variants will occur to those skilled in the art. In particular, the passivation layer may be a monolayer, and in this case, the step of forming of the first opening may be carried out by maintaining a residual thickness of said passivation layer at the bottom of the opening, that is, on the protection layer. The forming of the second opening is then performed preferably by maintaining this residual passivation layer thickness, or even by removing a small portion of passivation layer thickness. Further, other openings may be provided by implementing a method similar to the described method to access a copper line rather than the copper pad, or as a complement to the copper pad, while keeping a protection layer on the via. More generally, the method may be implemented to protect any copper interconnection element flush with an end of an interconnection structure likely to be submitted to an oxidizing and/or corrosive atmosphere, such as air.

Finally, the practical implementation of the described embodiments and variations is within the abilities of those skilled in the art based on the functional indications given hereabove.

A method of manufacturing an end of an interconnection structure (202) of an integrated circuit (200; 300; 400), the method may be summarized as including providing an integrated circuit including an interconnection structure (202) including copper interconnection elements (214, 216) at least partly extending through an insulating layer (212) and flush with a first surface (202A) of said interconnection structure; forming a protection layer (225) on the first surface of the interconnection structure, said protection layer including a material adapted to protecting the copper of the interconnection elements, for example from oxidation and/or from corrosion; forming a passivation layer (220) on the protection layer, the passivation layer having a first thickness (el); then forming a first opening (224) in the passivation layer across a second thickness (e2) smaller than the first thickness, to keep a residual passivation layer (221) at the bottom of the first opening.

The method may further include forming an additional insulating layer (226) in the first opening (224) and on the passivation layer (220); forming a second opening (227) in the additional insulating layer (226), vertically in line with the first opening (224), from a first surface (226A) of said additional insulating layer to the residual passivation layer (221); then removing the residual passivation layer (221) from the bottom of the first opening.

The second opening (227) may have greater lateral dimensions than the first opening (224).

The passivation layer (220) may be a multilayer structure including at least a first passivation layer (221), for example, made of silicon nitride, on the protection layer (225), and at least another layer (222, 223) on the first passivation layer (221), the first passivation layer (221) forming the residual passivation layer.

The at least another layer may include a dielectric layer (222), for example, made of silicon dioxide, on the first passivation layer (221) and a second passivation layer (223), for example, made of silicon nitride, on the dielectric layer.

The first thickness (e1) of the passivation layer (220) may be in the range from 710 to 1,340 nm and the thickness of the residual passivation layer (221) may be in the range from 10 to 40 nm.

The step of forming of the first opening and/or the step of forming of the second opening and/or the step of removal of the residual passivation layer may include a dry etching step.

The protection layer (225) may be formed by an atomic layer deposition technique; and/or the passivation layer (220) may be formed by a chemical vapor deposition technique, for example, a plasma-enhanced chemical vapor deposition technique.

The integrated circuit (200; 300; 400) may be summarized as including an interconnection structure (202) including copper interconnection elements (214, 216) at least partly extending through an insulating layer (212) and flush with a first surface (202A) of said interconnection structure, one end of the interconnection structure including a protection layer (225) on the first surface of the interconnection structure (202), said protection layer including a material adapted to protecting the copper of the interconnection elements, for example, from oxidation and/or from corrosion; a passivation layer (220) on the protection layer; and a first opening (224) in the passivation layer (220) extending all the way to the protection layer (225).

The interconnection structure end may further including an additional insulating layer (226) in the first opening (224) and on the passivation layer (220); and a second opening (227) in the additional insulating layer (226), vertically in line with the first opening (224), at least a portion of said second opening extending all the way to the protection layer (225).

The second opening (227) may have greater lateral dimensions than the first opening (224).

The passivation layer (220) may be a multilayer structure including a first passivation layer (221), for example, made of silicon nitride, on the protection layer (225); a dielectric layer (222), for example, made of silicon dioxide, on the first passivation layer (221); and a second passivation layer (223), for example, made of silicon nitride, on the dielectric layer (222).

The end of the interconnection structure may be obtained by implementing the method.

The integrated circuit (300; 400) may further include an electric contact element (302; 402) having a first end (302A; 402A) coupled to at least one of the interconnection elements (214, 216), the electric contact element being for example a wire (302), a pillar (402), and/or a ball.

The protection layer may be an insulating or dielectric material, in particular including aluminum and/or hafnium; and/or may have a thickness in the range from 1 nm to 100 nm, for example, from 5 nm to 50 nm.

The protection layer may be an insulating or dielectric material, in particular including aluminum and/or hafnium; and/or may have a thickness in the range from 1 nm to 100 nm, for example, from 5 nm to 50 nm.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an end of an interconnection structure of an integrated circuit, the method comprising:
providing an integrated circuit including an interconnection structure having copper interconnection elements at least partly extending through a first insulating layer and flush with a first surface of said interconnection structure;
forming a protection layer on the first surface of the interconnection structure, said protection layer including a material configured to protect the copper of the interconnection elements from one or both of oxidation or corrosion;
forming a passivation layer on the protection layer, the passivation layer having a first thickness; and
forming a first opening in the passivation layer across a second thickness smaller than the first thickness to keep a residual passivation layer at the bottom of the first opening.

2. The method according to claim 1, further comprising:
forming a second insulating layer in the first opening and on the passivation layer;
forming a second opening in the second insulating layer, vertically in line with the first opening, from a first surface of said second insulating layer to the residual passivation layer; and
removing the residual passivation layer from the bottom of the first opening.

3. The method according to claim 2, wherein the second opening has greater lateral dimensions than the first opening.

4. The method according to claim 1, wherein the passivation layer is a multilayer structure comprising at least a first passivation layer, for example, made of silicon nitride, on the protection layer, and at least another layer on the first passivation layer, the first passivation layer forming the residual passivation layer.

5. The method according to claim 4, wherein the at least another layer includes a dielectric layer, for example, made of silicon dioxide, on the first passivation layer and a second passivation layer, for example, made of silicon nitride, on the dielectric layer.

6. The method according to claim 1, wherein the first thickness of the passivation layer is in the range from 710 to 1,340 nm and the thickness of the residual passivation layer is in the range from 10 to 40 nm.

7. The method according to claim 1, wherein forming the first opening, forming the second opening, or removal of the residual passivation layer includes a dry etching step.

8. The method according to claim 1, wherein:
the protection layer is formed by an atomic layer deposition process; or
the passivation layer is formed by a plasma-enhanced chemical vapor deposition process.

9. The method of claim 1, wherein the first opening is vertically in line with at least one copper interconnection element of the copper interconnection elements, the first opening being formed.

10. The method according to claim 1, wherein:
the protection layer is an insulating or dielectric material including one or both of aluminum and hafnium; and
the protection layer has a thickness in a range from 1 nm to 100 nm;

11. The method of claim 1, wherein the protection layer has a thickness in a range from 5 nm to 50 nm.

12. An integrated circuit comprising;
a first insulating layer;
an interconnection structure including copper interconnection elements at least partly extending through the first insulating layer and flush with a first surface of the interconnection structure, one end of the interconnection structure including:
a protection layer on the first surface of the interconnection structure, said protection layer having a material configured to protect the copper of the interconnection elements from one or both of oxidation and corrosion;
a passivation layer on the protection layer; and
a first opening in the passivation layer extending all the way to the protection layer.

13. The integrated circuit according to claim 12, wherein the end of the interconnection structure further includes:
a second insulating layer in the first opening and on the passivation layer; and
a second opening in the second insulating layer, vertically in line with the first opening, at least a portion of said second opening extending all the way to the protection layer.

14. The integrated circuit according to claim 12, wherein the second opening has greater lateral dimensions than the first opening.

15. The integrated circuit according to claim 12, wherein the passivation layer is a multilayer structure including:
a first passivation layer of silicon nitride on the protection layer;
a dielectric layer of silicon dioxide on the first passivation layer; and
a second passivation layer of silicon nitride on the dielectric layer.

16. The integrated circuit according to claim 12, further comprising an electric contact element having a first end coupled to at least one of the interconnection elements, the electric contact element being a wire, a pillar, or a ball.

17. The integrated circuit according to claim 12, wherein the protection layer:
is an insulating or dielectric material, in particular including aluminum and/or hafnium; and/or
has a thickness in the range from 1 nm to 100 nm, for example, from 5 nm to 50 nm.

18. The integrated circuit of claim 12, wherein the first opening is vertically in line with at least one copper interconnection element of the copper interconnection elements, the first opening being formed.

19. An integrated circuit, comprising:
an interconnection structure including copper interconnection elements at least partly extending through an insulating layer and flush with a first surface of said interconnection structure, one end of the interconnection structure including:
a protection layer on the first surface of the interconnection structure, said protection layer comprising a material adapted to protecting the copper of the interconnection elements, for example, from oxidation and/or from corrosion;
a passivation layer having a first thickness on the protection layer;
a first opening in the passivation layer positioned vertically in line with at least one copper interconnection element of the copper interconnection elements, the first opening having a second thickness smaller than the first thickness; and
a residual passivation layer at the bottom of the first opening.

20. The integrated circuit of claim 19, wherein the interconnection structure end further includes:
an additional insulating layer in the first opening and on the passivation layer; and
a second opening in the additional insulating layer, vertically in line with the first opening, at least a portion of said second opening extending all the way to the residual passivation layer.

21-24. (canceled)
